(19) United States
(12) Patent Application Publication
(10) Pub. No.: US 2014/0148086 A1
(43) Pub. Date: May 29, 2014

(54) ADJUSTABLE AIR INLET DUCT FOR RACK SYSTEMS

(71) Applicant: INTERNATIONAL BUSINESS MACHINES CORPORATION, Armonk, NY (US)

(72) Inventors: Kevin M. Cash, Cary, NC (US); Aaron R. Cox, Tucson, AZ (US); Jason E. Minyard, Phoenix, AZ (US); Joni E. Saylor, Tucson, AZ (US)

(73) Assignee: INTERNATIONAL BUSINESS MACHINES CORPORATION, Armonk, NY (US)

(21) Appl. No.: 13/684,738

(22) Filed: Nov. 26, 2012

(51) Int. Cl. H05K 5/02

(52) U.S. Cl. CPC H05K 5/0213
USPC 454/184

(57) ABSTRACT

A method and apparatus is provided for providing air to a rack system. In one embodiment, the apparatus may include a duct adapted to channel air into a receiving section of the rack system. The apparatus may also include an adjustable separator within the duct to direct incoming air into partitions corresponding to the receiving section of the rack system before exiting the duct. The adjustable separator may have an adjustability of length and have a paneling made of a flexible material.

### TECHNICAL FIELD

Embodiments described herein generally relate to a controllable air inlet duct for rack systems, and more specifically to an apparatus, method, and system related to providing controlled and balanced air flow to electronic equipment contained in racks.

### BACKGROUND

The heat generated by electronic devices may be concentrated in locations where electrical components are placed in close proximity to one another. As one example, a rack system may contain densely packed electrical components. Accordingly, such racks may generate a substantial amount of localized heat during operation. The ability to control and remove this heat may affect performance, efficiency, and lifespan of electronic components contained and used in rack systems.

### SUMMARY

In one embodiment, a method is provided for providing air to a rack system. The method may include adapting a duct to channel air into a receiving section of the rack system. The method may further include, directing incoming air into partitions corresponding to the receiving sections of the rack system before exiting the duct using an adjustable separator within the duct. The adjustable separator may have an adjustability of length and have a paneling made of a flexible material.

In another embodiment, an apparatus is provided for providing air to a rack system. The apparatus may include a duct adapted to channel air into a receiving section of the rack system. The apparatus may also include an adjustable separator within the duct to direct incoming air into partitions corresponding to the receiving section of the rack system before exiting the duct. The adjustable separator may have an adjustability of length and have a paneling made of a flexible material.

### BRIEF DESCRIPTION OF THE DRAWINGS

FIG. 1 shows a schematic representation of a server, according to one embodiment of the invention.

FIG. 2 shows a schematic side view representation of a server and a duct, according to one embodiment of the invention.

FIG. 3 shows a schematic side view representation of a duct, according to one embodiment of the invention.

FIG. 4 shows a schematic representation of an adjustable separator, according to one embodiment of the invention.

FIG. 5 shows a schematic representation of an air guide extension, according to one embodiment of the invention.

In the Figures and the Detailed Description, like numbers refer to like elements.

### DETAILED DESCRIPTION

Often heat must be removed from an electronic component and its immediate area in order for the component to maintain an operational temperature within desired limits. Failure to remove heat effectively results in increased component temperatures, which in turn, may lead to thermal runaway conditions causing decreased performance and potentially catastrophic failure. Thermal management is the process of maintaining a desirable temperature in electronic devices and their surroundings. The need to cool current and future high heat load, high heat flux electronic components and systems therefore mandates the development of aggressive thermal management techniques.

Rack system may contain multiple electronic devices for which thermal management is desired. In one embodiment, the electronic devices may be servers. In other embodiments, the rack system may contain electronic storage or networking hardware. Traditionally, rack systems may be kept in rooms that have carefully controlled temperature and humidity levels. For more powerful rack systems that may run at higher temperatures this may not be enough for maintaining proper temperature of contained electronics. For rack systems that require greater thermal management, ducts may be attached so that air may be directed through the rack system for better thermal maintenance. In various embodiments, the temperature of the air, the volume of air, the velocity of the air and the humidity of the air being channeled through the ducts may be controlled. Previously ducts for rack systems may have greatly limited configurability and adjustability. Previous ducts may have used metal sheet as separators. The separators may be used for directing or dividing air channeled through the duct into the rack system. These separators may typically be made of metal and thus a nonadjustable length. The size and shape of a duct may limit the angles that such separators may be used at, thereby limiting their use in dividing and directing air flow. This may mean that if rack system is modified or if the duct is applied to a different rack system, the duct may not channel air where needed without difficult and time consuming part replacement.

Features illustrated in the drawings are not necessarily drawn to scale. Descriptions of well-known components and processing techniques are omitted so as to not unnecessarily obscure the embodiments of the invention. The examples used herein are intended merely to facilitate an understanding of ways in which the embodiments may be practiced and to further enable those of skill in the art to practice the invention. It is also to be understood that the descriptions of the embodiments are provided by way of example only, and are not intended to limit the scope of this invention as claimed.

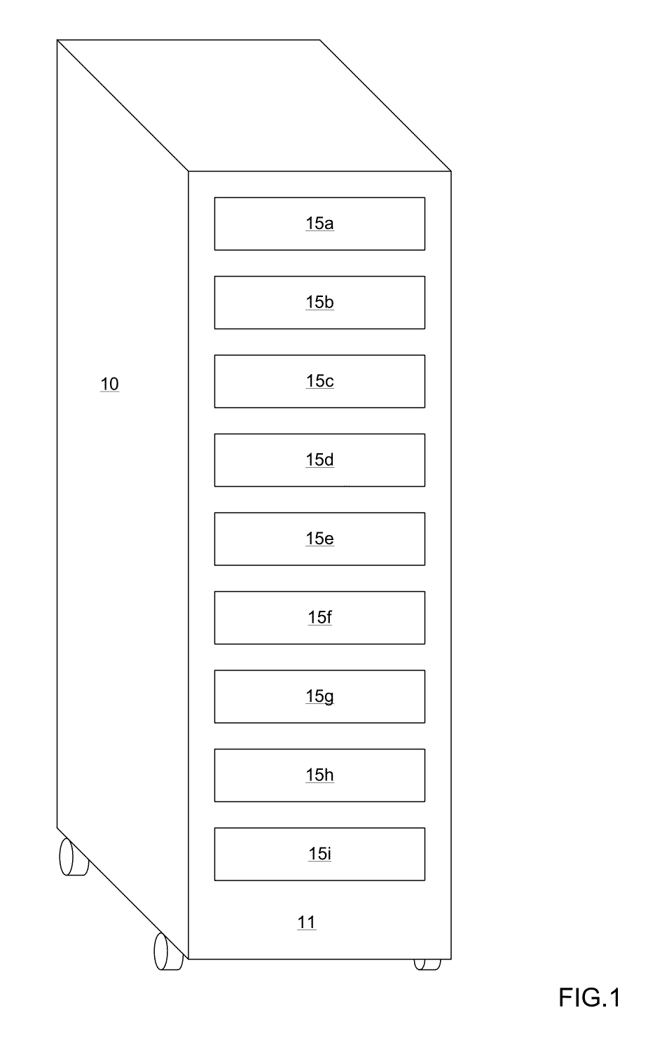

FIG. 1 is a schematic representation of one embodiment of a rack system, in this illustration a server rack 10. The server rack 10 may have receiving section that may be designed or adapted to receive a duct supplying air. In the shown embodiment, the receiving section is one side, or face 11, of the server rack 10. In various embodiments the receiving section may vary in size, shape, and placement on the server rack 10. The illustrated embodiment shows the rear or back of the server rack 10 as the receiving section face 11. In other embodiments, the receiving face may be the sides or front of the server rack 10. One skilled in the art will appreciate the variety of locations and forms these receiving sections may take.

In the shown embodiment, the receiving section of the server, face 11, may have panels 15a through 15i (collectively referred to as 15) designed to receive the air from a duct. These panels 15 when removed or opened may allow for air from an attached duct to flow into the server rack 10. In various embodiments, the panels 15 may be screwed on plates, pop-out pieces, or hinged plates. The opening or removal of specific panels 15 may result in air flowing over specific components in the server rack 10. This may result in improved thermal control of such components. For example, the opening of only panels 15c, 15d, and 15e may result in a majority of the volume of air from the duct attached to receiving face flowing over and around components located behind panels 15c, 15d, and 15e. In various embodiments the number of panels 15 may vary or the panels may be replaced by one or more openings on receiving face of the server. In another embodiment, the panels 15 may be replaced with screening or may be one or more uncovered openings for allowing for air to pass through into the server rack 10.

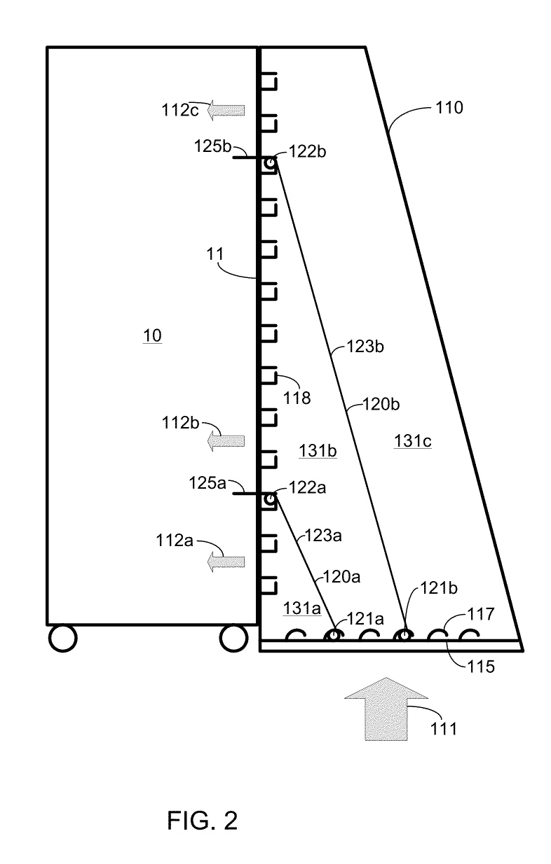

FIG. 2 is a schematic representation of one embodiment of a server rack 10 and a duct 110. Incoming air 111 may, for example, enter the duct 110 from the bottom and be channeled out the left side as exiting air 112 composed of air groups 112a, 112b, 112c created from respective partitions 131a, 131b, and 131c. The partitions may be created by using adjustable separators 120. Thus when duct 110 is joined, connected, coupled with, or placed adjacent to the face 11 of the server rack 10 incoming air 111 supplied to the duct 110 may be channeled through and into the server rack 10 in distinct and focused areas. The incoming air 111 may be channeled to the duct 110 through vents that are part of a system to feed one or more servers 10 with air. In one embodiment, the duct 110 may be adapted to receive incoming air 111 from vented floor tiles.

In the embodiment shown, the duct 110 has a mounting bracket 115. The mounting bracket 115 has a multitude of retainers 117 attached thereto. The mounting bracket 115 and retainers 117 may create a plurality of attachment points in the duct 110 for the bases 121 of the adjustable separators 120. In other embodiments, the duct may have a multitude of mounting brackets and retainers. In another embodiment, the duct may have no mounting bracket for the retainers 117 and instead the retainers may be mounted, built into, or part of the walls, sides, or floor of the duct 110.

In the embodiment shown, the duct 110 may have a multitude of holders 118. The holders 118 may create a plurality of attachment points in the duct 110 for the connectors 122 at the end of the adjustable separators 120. In other embodiments, the duct 110 may use a mounting bracket 115 for attaching the holders 118. In another embodiment, the duct 110 may have the mounting brackets 115 built into, mounted, or part of the walls, sides, top of the duct 110.

The retainers 117 and holders 118 may be used for mounting opposing ends of the adjustable separators 120a and 120b (collectively referred to as 120). The adjustable separators 120 may have respective bases 121a and 121b, paneling 123a and 123b, and end with connectors 122a and 122b. The bases 121 may be installed to any of the retainers 117. The connectors 122, which are the located on the ends of the adjustable separators 120 opposite the bases 121, may be installed to any of the holders 118. The adjustable separator 120 may be installed to any combination of retainer 117 and holder 118. The paneling 123 may adjust to the various combinations of lengths possible using the retainer 117 and holders 118. In various embodiments, the use of the retainers 117, holders 118, bases 121, and the connectors 122 may be rearranged with respect to these elements use at either the entrance or exit of the duct 110. The selection of various retainers 117 and holders 118 for the adjustable separators 120 may create partitions for the incoming air 111 such as 131a, 131b, and 131c. The partitions 131 may be adjusted by selecting either a different retainer 117 or holder 118, or both, for the adjustable separator 120. The paneling 123 may be adjustable to accomplish the required adaptability, and is discussed below.

The embodiment shown also has optional air guides 125a and 125b. The air guides may be used to further direct exiting air groups 112a, 112b, and 112c to specific areas or components within the server rack 10 as they leave the duct 110. The air guides may be attached to the adjustable separators 120 at either the connectors 122 or the paneling 123.

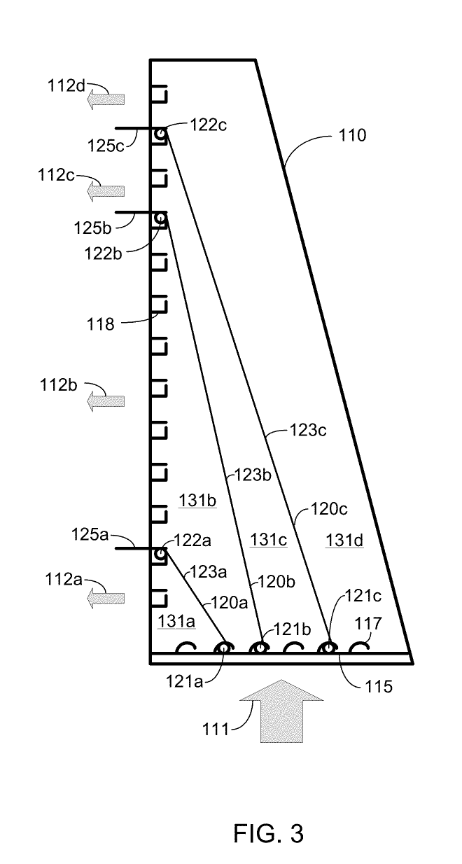

FIG. 3 shows a schematic representation of one embodiment of a duct 110. The duct 110 shown may be the same as shown in FIG. 2 with the addition of a third adjustable separator 120c creating a fourth partition of 131d. The position of the previous adjustable separators 120a and 120b have been altered to show the variance in positioning the adjustable separators 120 may provide. The embodiment shown illustrates how modification of the number and positioning of the adjustable separators 120 may vary the partitions 131 in location and separation of incoming air 111 distributed to air groups 112a, 112b, 112c, and 112d. Airflow may be distributed by adjusting how much incoming air 111 enters each partition 131 created by the adjustable separators 120 by using different retainers 117 for each base 121. Exiting air partitions 112a-112d may be focused on specific areas or components in the server rack 10 by using different holders 118 for each connector 122. For example, the volume of air in exiting air group 112b may be at a low velocity. This may be caused by positioning adjustable separators 120a and 120b close together at respective bases 121a and 121b, and far apart at connections 122a and 122b. This may result in the partition 131b distributing exit air group 112b over a larger portion of the server that can effectively diffuse the air and reducing the velocity of air group 112b. By comparison, the velocity and volume of air in air group 112c that passes through partition 112c may be larger than air group 112b. This may be caused by the larger gap between bases 121b and 121c, which may allow more of incoming air 11 in to partition 131c. Connection points 122b and 122c may also be positioned closer together which may concentrate air group 112 and distribute it over a smaller area of the server rack 105. In various embodiments, the location and use of adjustable separators 120 may be combined with the use and opening of panels 15 on the server rack 10 to direct exiting air groups 112 to specific components. In various embodiments, the adjustable separators 120 may also be used to avoid sending air to unpopulated portions or empty spots of the server rack 10.

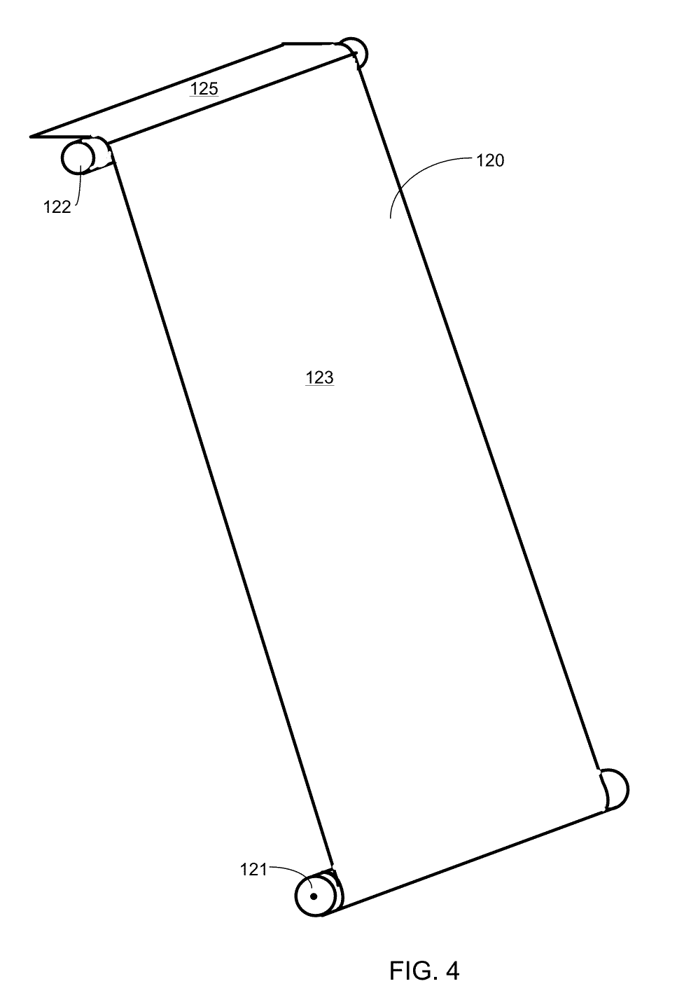

FIG. 4 shows a schematic representation of one embodiment of an adjustable separator 120. As previously mentioned, the adjustable separator 120 may include several elements. The base 121 may connect to, couple with, latch on, or engage with retainers 117 so that the adjustable separator 120 may intercede and separate part of the incoming air 111 of the duct 110. In the shown embodiment, the base 121 may be a rod shaped element attached to one end of the paneling 123 with ends of the rod that extend past the edges of the paneling 123. The ends of the rod may be inserted into the retainers 117 for mounting the end of the adjustable separator 120 in the duct 110. Similarly, the connector 122 is shown as rod shaped element that may be attached to the opposite edge of the paneling 123 from the base 121. The connector 122 also may have ends that extend past the edge of the paneling 123. The ends of the rod used of the connector 122 may be inserted into holders 118 for mounting or securing the end of the adjustable separator 120. The use of a rod like element for the base 121 or connector 122 is exemplary only, and the forms of the base 121 and connectors 122 along with the retainers 117 and holders 118 may vary greatly in other embodiments. In other embodiments the use of hooks and eyes may be used for either the base 121 and retainers 117 or the connector 122 and holders 118. Various other embodiments may include the use of snaps, zippers, latches, magnets, screws, buttons, or quick connects. One skilled in the art will appreciate the variety of factors and forms these elements may take.

The adjustable separator 120 may adjust to various lengths by using paneling 123 that can vary in length to meet the range of possible needs in a duct 110. The paneling 123 may be a flexible material such as a soft plastic, vinyl, nylon, or cloth. The use of flexible materials for the paneling 123 may provide for the adjustability of lengths and angles created when using various retainers 117 and holders 118. In one embodiment, the paneling material may also be elastic, for example a spandex material, allowing for it to be stretched to match different lengths needs. Other embodiments may use mechanical means to assist in adjusting the length of the panel 120. In various embodiments, the panel 120 may wrap around the base 121. For example in one embodiment, base 121 may include a spring roller mechanism and housing that may allow for the length of the panel 120 to be adjustable. In another embodiment, the base 121 may include the housing for holding accordion folds of paneling 123 which may allow for adjustment in the length of the paneling 123.

In the embodiment shown in FIG. 4, an air guide 125 may be attached to the connector 122 or the paneling 123. This air guide 125 may be used to further direct air flow into specific areas of the server rack 10 as shown in FIG. 2. This air guide 125 may insert into the server rack 10. Servers 10 may have gaps, hollow spaces, and openings between the server housing and components installed within the server rack 10. These gaps may result due to the need for the housing to accommodate various sizes of electronic equipment and components. The gaps may also be created by the need to accommodate connects between the electronics housed in the server rack 10 such as power cables and communication cables. These gaps may result in diffusion of the exiting air groups 112 as it exits the duct 110 and enters the server rack 10. This may result in reduced air flow over targeted components within the server rack 10. One possible advantage of the use of the air guide 125 may be that the exiting air groups 112 will diffuse less upon entry into the server rack 10 as one direction of diffusion may be blocked. The lack of diffusion may result in improved air flow over targeted components.

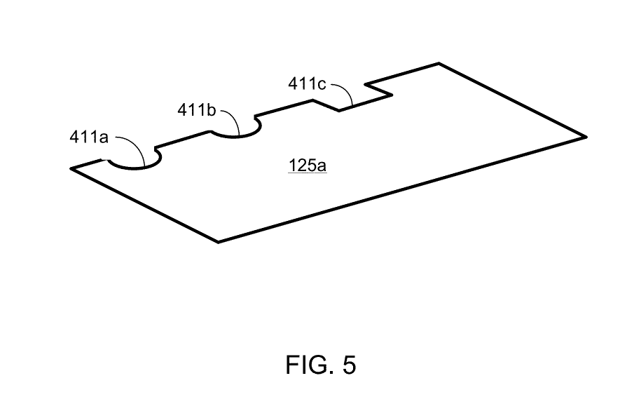

FIG. 5 shows a schematic representation of an embodiment of the air guide 125a that may extend into a server rack 10. The air guide 125a may be a solid panel shaped to fit an opening on a server for receiving exiting air 112 from a duct 110. In one embodiment, the air guide 125a may have an approximate width equal to the width of the panels 15 on the server rack 10. The exemplary embodiment includes cut-outs 411a, 411b, and 411c (collectively referred to as 411). In one embodiment, the cut-out 411 may be matched in shape and placement to specific components in the server. In another embodiment, the cut-out 411 may be generically shaped and placed to allow for common components in the server rack 10 such as wires and cables.

In another embodiment, the air guide may be made of a multitude of filaments. Specifically, an air guide 125a may be a row of brush-like filaments or bristles set into a rod or elongated member. In one embodiment, the rod or elongated member may be placed substantially parallel to the connector 122. In another embodiment, the rod or elongated member may be part of the connector 122. The filaments may extend perpendicularly from the elongated member into the rack system. In such an embodiment, the filaments may act semi-rigid curtain, solid enough to direct air while flexible enough to conform around components they come in contact with.

While the disclosed subject matter has been described with reference to illustrative embodiments, this description is not intended to be construed in a limiting sense. Various modifications of the illustrative embodiments, as well as other embodiments of the subject matter, which are apparent to persons skilled in the art to which the disclosed subject matter pertains are deemed to lie within the scope and spirit of the disclosed subject matter.

What is claimed is:

1. An apparatus for providing air to a rack system, comprising:
a duct adapted to channel air into a receiving section of the rack system;
an adjustable separator within the duct to direct incoming air into partitions corresponding to the receiving section of the rack system before exiting the duct, the adjustable separator to have an adjustability of length and have a paneling made of a flexible material.

2. The apparatus of claim 1, further comprising a spring roller integrated into the adjustable separator for adjusting the length of the paneling.

3. The apparatus of claim 1, further comprising an air guide attached to the end of the adjustable separator, wherein the air guide extends into the rack system.

4. The apparatus of claim 3, wherein the air guide includes a cut out section for components within the rack system.

5. The apparatus of claim 3, wherein the air guide comprises a multitude of filaments.

6. The apparatus of claim 1, wherein the paneling is made of an elastic material.

7. The apparatus of claim 1, wherein the duct is adapted to accept air from vented floor tiles.

8. The apparatus of claim 1, further comprising a plurality of attachment points positioned in the duct to hold a base of the adjustable separator.

9. The apparatus of claim 1, further comprising a plurality of attachment points positioned in the duct to hold an end of the adjustable separator.

10. A method for providing air to a rack system, comprising:
adapting a duct to channel air into a receiving section of the rack system;
directing incoming air into partitions corresponding to the receiving sections of the rack system before exiting the duct using an adjustable separator within the duct, the adjustable separator to have an adjustability of length and have a paneling made of a flexible material.

11. The method of claim 10, wherein a spring roller integrated into the adjustable separator is used for adjusting the length of the paneling.

12. The method of claim 10, further comprising attaching an air guide to an end of the adjustable separator, wherein the air guide extends into the rack system.

13. The method of claim 12, wherein the air guide includes a cut out section for components within the rack system.

14. The method of claim 12, wherein the air guide comprises a multitude of filaments.

15. The method of claim 10, wherein the paneling is made of an elastic material.

16. The method of claim 10, wherein the duct is adapted to accept air from vented floor tiles.

17. The method of claim 10, further comprising creating a plurality of attachment points positioned in the duct to hold a base of the adjustable separator.

18. The method of claim 10, further comprising creating a plurality of attachment points positioned in the duct to hold an end of the adjustable separator.
